(19) United States
(12) Patent Application Publication
(10) Pub. No.: US 2025/0040298 A1
(43) Pub. Date: Jan. 30, 2025

(54) LIGHT EMITTING DIODE

(71) Applicant: Quanzhou sanan semiconductor technology Co., Ltd., Fujian (CN)

(72) Inventors: Kunta HSIEH, Fujian (CN); Fangfang LIN, Fujian (CN); Tao HAN, Fujian (CN); Xinxin YANG, Fujian (CN); Zhaojun WEN, Fujian (CN); Chung-Ying CHANG, Fujian (CN)

(73) Assignee: Quanzhou sanan semiconductor technology Co., Ltd., Fujian (CN)

(21) Appl. No.: 18/915,246

(22) Filed: Oct. 14, 2024

Related U.S. Application Data
(63) Continuation of application No. PCT/CN2022/133187, filed on Nov. 21, 2022.

(30) Foreign Application Priority Data
Apr. 18, 2022 (CN) 202210401670.9

(51) Int. Cl. H01L 33/12; H01L 33/20

(52) U.S. Cl. CPC H01L 33/12; H01L 33/20

(57) ABSTRACT

The disclosure relates to a technical field of a semiconductor optoelectronic device, and more particularly, to a light emitting diode and a light emitting device. To solve an issue that a metal layer of the existing light emitting diode has insufficient adhesion on an insulation layer, the light emitting diode includes a semiconductor epitaxial stack layer including a first conductive semiconductor layer, a light emitting layer, and a second conductive semiconductor layer sequentially stacked and disposed; an interface transition layer located above the semiconductor epitaxial stack layer; the interface transition layer including an insulation metal oxide or a stack layer of the insulation metal oxides; a first insulation layer disposed between the interface transition layer and the semiconductor epitaxial stack layer; the metal layer covering a portion of a surface of the interface transition layer and electrically connected to the semiconductor epitaxial stack layer.

### CROSS-REFERENCE TO RELATED APPLICATION

This application is a continuation of international application of PCT application serial no. PCT/CN2022/133187 filed on Nov. 21, 2022, which claims the priority benefit of China application no. 202210401670.9 filed on Apr. 18, 2022. The entirety of each of the above-mentioned patent applications is hereby incorporated by reference herein and made a part of this specification.

### BACKGROUND

### Technical Field

The disclosure relates to a technical field of a semiconductor optoelectronic device, and more particularly, to a light emitting diode and a light emitting device.

### Description of Related Art

A light emitting diode (LED) includes different light emitting materials and light emitting components and is a solid-state semiconductor light-emitting element. It is widely used in various scenarios such as lighting, visible light communication, and light emitting display due to its advantages such as low cost, low power consumption, high luminous efficiency, small size, energy saving and environmental protection, and good optoelectronic properties. A metal layer of the existing light-emitting diode has insufficient adhesion force to the insulation layer.

### SUMMARY

In order to solve an issue that a metal layer of an existing light emitting diode has insufficient adhesion on an insulation layer, the disclosure provides a light emitting diode with high reliability.

Technical solutions adopted in the embodiment of the disclosure are as follows.

Specifically, an embodiment of the disclosure provides a light emitting diode, including:
a semiconductor epitaxial stack layer including a first conductive semiconductor layer, a light emitting layer, and a second conductive semiconductor layer sequentially stacked and disposed;
an interface transition layer located on the semiconductor epitaxial stack layer;
a first insulation layer disposed between the interface transition layer and the semiconductor epitaxial stack layer;
a metal layer covering a portion of a surface of the interface transition layer and electrically connected to the semiconductor epitaxial stack layer.

The disclosure improves the adhesion force between the metal layer and the insulation layer by disposing the interface transition layer including an insulation metal oxide or a stack layer of the insulation metal oxides, thereby improving the reliability of the light emitting diode.

Other features and beneficial effects of the disclosure will be set forth in the following specification, and will in part become apparent from the specification, or may be understood by implementation of the disclosure. The objectives and other beneficial effects of the disclosure may be realized and obtained through the structures particularly pointed out in the specification, claims, and drawings.

In order to more clearly illustrate the embodiments of the disclosure or the technical solutions in the related art, the following briefly introduces the drawings required for use in the embodiments or the description of the related art. Obviously, the drawings in the following description are some embodiments of the disclosure. For those skilled in the art, other drawings may be obtained based on these drawings without exerting creative efforts. In the following description, unless otherwise specified, positional relationships described in the accompanying drawings are based on directions in which the components are drawn in the drawings.

### BRIEF DESCRIPTION OF THE DRAWINGS

FIG. 1 is a schematic top view of a light emitting diode according to an embodiment of the disclosure.

FIG. 2A is a schematic cross-sectional side view of a light emitting diode according to the first embodiment of the disclosure.

FIG. 2B is a schematic enlarged view of a structure in a dashed frame in FIG. 2A.

FIG. 2C is a schematic enlarged view of the structure in the dashed frame in FIG. 2A according to the second embodiment of the disclosure.

FIG. 2D is a schematic enlarged view of the structure in the dashed frame in FIG. 2A according to a modified embodiment of the first embodiment of the disclosure.

FIG. 2E is a schematic enlarged view of the structure in the dashed frame in FIG. 2A according to another modified embodiment of the first embodiment of the disclosure.

FIG. 3A is a schematic cross-sectional side view of a light emitting diode according to the third embodiment of the disclosure.

FIG. 3B is a schematic enlarged view of a structure in a dashed frame in FIG. 3A.

FIG. 4 is a schematic cross-sectional view of a light emitting diode according to the fourth embodiment of the disclosure.

FIG. 5 is a schematic cross-sectional view of the light emitting diode according to a modified embodiment of the fourth embodiment shown in FIG. 4.

FIG. 6 is a schematic cross-sectional view of a light emitting diode according to the fifth embodiment of the disclosure.

FIG. 7 is a schematic cross-sectional view of the light emitting diode according to a modified embodiment of the fifth embodiment shown in FIG. 6.

FIG. 8 is a schematic top view of a portion of a structure of a light emitting diode according to the sixth embodiment of the disclosure.

FIG. 9A is a schematic side view of the light emitting diode provided in the sixth embodiment.

FIG. 9B is a schematic enlarged view of a structure in a dashed frame in FIG. 9A.

FIG. 9C shows the first modified embodiment of the structure in the dashed frame in FIG. 9A according to the sixth embodiment of the disclosure.

FIG. 9D shows the second modified embodiment of the structure in the dashed frame in FIG. 9A according to the sixth embodiment of the disclosure.

FIG. 10A is a schematic side view of a structure of a light emitting diode according to the seventh embodiment of the disclosure.

FIG. 10B is a schematic enlarged view of the structure in a dashed frame in FIG. 10A.

FIG. 10C shows the first modified embodiment of the structure in the dashed frame in FIG. 10A according to the seventh embodiment of the disclosure.

FIG. 11 is a schematic cross-sectional view of a light emitting diode according to the eighth embodiment of the disclosure.

FIG. 12 is a schematic cross-sectional view of a light emitting diode according to the ninth embodiment of the disclosure.

FIG. 13 is a schematic cross-sectional view of a light emitting diode according to the tenth embodiment of the disclosure.

FIG. 14 is a schematic cross-sectional view of a light emitting diode according to the eleventh embodiment of the disclosure.

FIG. 15 is a schematic view of a structure of a light emitting device provided in the disclosure.

### DETAILED DESCRIPTION OF DISCLOSED EMBODIMENTS

A light emitting diode provided in an embodiment of the disclosure includes a semiconductor epitaxial stack layer 20, an interface transition layer 30, a first insulation layer 50, and a metal layer 60.

The semiconductor epitaxial stack layer 20 is disposed on a substrate 10. The substrate may be a transparent substrate 10, a non-transparent substrate 10, or a semi-transparent substrate 10, and has an upper surface 11 and a lower surface 12 opposite to each other. The transparent substrate 10 or the semi-transparent substrate 10 may allow light irradiated from the semiconductor epitaxial stack layer 20 to pass through the upper surface 11 of the substrate 10 and reach the lower surface 12 of the substrate 10 away from the semiconductor epitaxial stack layer 20. For example, the substrate 10 may be a growth substrate used to grow the semiconductor epitaxial stack layer 20, including a sapphire substrate, a silicon nitride substrate, a silicon substrate, a gallium nitride substrate, an aluminum nitride substrate, etc. However, the embodiments of the disclosure are not limited thereto. A thickness of the substrate 10 is preferably not more than a length of a short side of a chip. In some embodiments, the thickness of the substrate 10 is less than 300 μm, which may be, for example, 200 μm, 100 μm, or 80 μm. In addition, in some embodiments, the substrate 10 may be thinned or removed to form a thin film chip.

The substrate 10 may include an uneven structure (not shown) formed in at least one partial area of the upper surface 11 thereof. The uneven structure may improve external light extraction efficiency and crystallinity of a semiconductor layer constituting the semiconductor epitaxial stack layer 20. For example, a common example is a dome-shaped convex shape, or it may be other various shapes, such as a platform, a cone, a triangular pyramid, a hexagonal pyramid, a quasi-cone, a quasi-triangular pyramid or a quasi-hexagonal pyramid, etc., or a combination thereof. In addition, the uneven structure may be selectively formed at various areas, such as the lower surface 12 of the substrate 10 to improve the light extraction efficiency, or may be omitted. In some specific implementations, a material of the uneven structure may be the same as a material of the substrate 10, or may be different from the material of the substrate 10. At this time, the refractivity of the uneven structure is preferably lower than the refractivity of the substrate, which is beneficial to improving the light extraction efficiency of the chip. In some other embodiments, the uneven structure may also be a multi-layer structure, and different material layers have different refractivity. Thus, details in this regard will not be further reiterated in the following.

The semiconductor epitaxial stack layer 20 includes a first conductive semiconductor layer 21, a light emitting layer 22, and a second conductive semiconductor layer 23 which are sequentially stacked and disposed. A material of the semiconductor epitaxial stack layer includes group III-V semiconductor materials of AlₓIn_{y}Ga_{(1-x-y)}N or AlₓIn_{y}Ga_{(1-x-y)}P, where 0≤x, y≤1, and x+y≤1. According to a material of the light emitting layer, when the material of the semiconductor epitaxial stack layer is a series of AlInGaP, red light with a wavelength between 610 nm and 650 nm or yellow light with a wavelength between 550 nm and 570 nm may be emitted. When the material of the semiconductor epitaxial stack layer is a series of InGaN, blue light or deep blue light with a wavelength between 400 nm and 490 nm or green light with a wavelength between 490 nm and 550 nm may be emitted. When the material of the semiconductor epitaxial stack layer is a series of AlGaN, UV light with a wavelength between 400 nm and 250 nm may be emitted. The light emitting layer 22 may be a single heterostructure (SH), a double heterostructure (DH), a double-side doubleheterostructure (DDH), and a multi-quantum well (MQW). A material of the light emitting layer 22 may be an i-type, p-type, or n-type semiconductor.

Before the first conductive semiconductor layer 21 is formed, a buffer layer (not shown) may be formed on the upper surface 11 of the substrate 10 to improve lattice mismatch between the substrate 10 and the semiconductor epitaxial stack layer 20. The buffer layer may be formed by a material of a series of gallium nitride (GaN).

It should be noted that the light emitting diode in the disclosure is not limited to including only one semiconductor epitaxial stack layer 20, but may also include multiple semiconductor epitaxial stack layers 20 located on the substrate 10. A conductive structure may be provided between the semiconductor epitaxial stack layers 20, so that the semiconductor epitaxial stack layers 20 are electrically connected to each other on the substrate 10 in in series, parallel, series-parallel, etc.

Optionally, a current expansion layer 40 may be further disposed on the semiconductor epitaxial stack layer 20 to expand a current, so that current distribution is more uniform, an operating voltage of the light emitting diode is reduced, and light emitting performance of the light emitting diode is improved. The current expansion layer 40 may be made of a transparent conductive material, and the transparent conductive material may include indium tin oxide (ITO), indium zinc oxide (IZO), indium oxide (InO), tin oxide (SnO), cadmium tin oxide (CTO), antimony tin oxide (ATO), aluminum zinc oxide (AZO), zinc tin oxide (ZTO), gallium doped zinc oxide (GZO), tungsten doped indium oxide (IWO), or zinc oxide (ZnO). However, the embodiments of the disclosure are not limited thereto.

A thickness of the current expansion layer 40 is generally not limited, but as a preferred embodiment, the thickness may be in a range of about 50 Å to 3000 Å, and more preferably, may be in a range of 50 Å to 1500 Å. If the thickness of the current expansion layer 40 is too thick, the light passing through the current expansion layer 40 is absorbed, and loss occurs. Therefore, the thickness of the current expansion layer 40 is generally limited to less than 3000 Å.

The first insulation layer 50 is located on the semiconductor epitaxial stack layer 20. The first insulation layer 50 may be one of SiO₂, SiN, SiOₓN_{y}, TiO₂, Si₃N₄, Al₂O₃, TiN, AlN, ZrO₂, TiAlN, TiSiN, HfO₂, TaO₂ or MgF₂, or a distributed Bragg reflector (DBR) formed by repeatedly stacking two or more materials. The first insulation layer 50 has different functions according to a position where it is disposed. For another example, the first insulation layer 50 located on a side surface of the semiconductor epitaxial stack layer 20 close to the second conductive semiconductor layer 23 may be made of a reflective insulation material and may be used to reflect light and block different electrodes in the light emitting diode. However, the embodiments of the disclosure are not limited thereto. A second insulation layer 70 has a patterned second through-hole structure 501, so that the metal layer 60 may be electrically connected to the current expansion layer 40 through the second through-hole structure 501. In order to make the first insulation layer 50 have better insulation protection and anti-leakage performance, in some preferred embodiments, a thickness of the first insulation layer 50 is selected to be between 50 and 2400 nm, which may be, for example, 200 nm or more, 300 nm or more, or 1 μm or more. A diameter of the second through-hole structure 501 may be greater than 3 μm and less than 20 m, and more preferably, greater than 6 μm and less than 12 μm. If the diameter of the second through-hole structure 501 is too small, it may easily cause a current congestion effect, resulting in a voltage increase. A distance between the adjacent second through-hole structures 501 may be greater than 10 μm and less than 50 μm.

The interface transition layer 30 is located on the semiconductor epitaxial stack layer 20, which may be an insulation metal oxide or a stack layer of insulation metal oxides. In the related art, a method in which the metal layer 60 is directly in contact with the insulation layer (SiO₂) is usually adopted as a common structure, resulting in insufficient adhesion force of the metal layer 60 on the insulation layer, and the metal layer 60 is prone to fall off. In the disclosure, there is a better correlation between the insulation metal oxide and the metal material, and a structure in which the metal layer 60 formed by the metal material is directly in contact with the interface transition layer 30 formed by the insulation metal oxide is selected instead of the first insulation layer 50, which may effectively improve the adhesion force of the metal layer 60 in the light emitting diode, that is, adhesion force in a chip structure, thereby improving reliability of the light emitting diode. Preferably, the insulation metal oxide may include at least one of TiO₂, ZrO₂, HfO₂, Ta₂O₅, Al₂O₃, Nb₂O₅, Y₂O₃, MgO, La₂O₃, SrTiO₃, BaTiO₃, and CeO₂. The materials have good compactness and better side coating of the semiconductor epitaxial stack layer 20, thereby further improving reliability of the chip.

A thickness of the interface transition layer 30 may be greater than 3 nm and less than 400 nm, so as to complete film formation of the insulation metal oxide and make it have a complete interface, thereby forming good adhesion force at the interface in contact with the metal layer 60. In addition, the interface transition layer 30 formed by the insulation metal oxide may improve the reliability of the metal layer 60 by increasing the thickness of the interface transition layer 30 within a certain range. As a preferred embodiment, in order to make the metal layer 60 have better adhesion performance on the interface transition layer 30, the thickness of the interface transition layer 30 is preferably less than 200 nm, thereby effectively reducing other peeling risks of the metal layer 60 due to an increase in stress caused by excessive thickness. In some embodiments, in order to meet actual production requirements, the thickness of the interface transition layer 30 may be greater than 10 nm and less than 200 nm. In other embodiments, the thickness of the interface transition layer 30 may be greater than 20 nm and less than 100 nm, or greater than 20 nm and less than 50 nm, so as to form a better optical film effect. The interface transition layer 30 may be implemented by vapor deposition, atomic layer deposition, and other processes. For example, the atomic layer deposition may be adopted to form a good film-forming state at a deposition thickness of 3 nm. In other embodiments, the refractivity of the interface transition layer 30 may be greater than 1.5 and less than 3.5. In combination with a certain thickness and refractivity, the interface transition layer 30 may not only improve the adhesion force of the metal layer 60, but also form an optical functional layer with the variable refractivity in its own stack layer or in cooperation with the first insulation layer 50 to improve the light extraction efficiency. The interface transition layer 30 may have a patterned first through-hole structure 301, so that the metal layer 60 may be electrically connected to the current expansion layer 40 through the first through-hole structure 301. A diameter of the first through-hole structure 301 may be greater than 3 μm and less than 20 μm, and more preferably, greater than 6 m and less than 12 μm. If the diameter of the first through-hole structure 301 is too small, it may easily cause the current congestion effect, resulting in the voltage increase. A distance between the adjacent first through-hole structures 301 may be greater than 10 μm and less than 50 μm.

The metal layer 60 covers a portion surface of the interface transition layer 30. To ensure that the light emitting diode has better light emitting efficiency, the metal layer 60 may include a metal reflective layer 61, and a material of the metal reflective layer 61 may include Ag, Al, Rh, etc. The metal layer 60 may further include a metal barrier layer 62. The metal barrier layer 62 covers a surface of the metal reflective layer 61, and the surface may be understood as an upper surface and an edge side wall, so as to prevent the metal reflective layer 61 from diffusing. A material thereof may include TiW, Cr, Pt, Ti, Ni, W, etc.

The light emitting diode further includes the second insulation layer 70 located on the first insulation layer 50 and optionally covering a portion of an upper surface of the first insulation layer 50 and a portion of an upper surface and a side wall of the metal layer 60 or covering a portion of an upper surface of the interface transition layer 30 and the portion of an upper surface and the side wall of the metal layer 60. The second insulation layer 70 may be one of SiO₂, SiN, SiOₓN_{y}, TiO₂, Si₃N₄, Al₂O₃, TiN, AlN, ZrO₂, TiAlN, TiSiN, HfO₂, TaO₂ or MgF₂, or the distributed Bragg reflector (DBR) formed by repeatedly stacking two or more materials. In some embodiments, the second insulation layer 70 may be an insulating reflective layer, and may be a multi-layer film structure formed by alternately stacking different high refractive dielectric films and different low refractive dielectric films. A material of the high refractive dielectric film may be TiO₂, NB₂O₅, TA₂O₅, HfO₂, ZrO₂, etc. A material of the low refractive dielectric film may be SiO₂, MgF₂, Al₂O₅, SiON, etc. With such configuration, the second insulation layer 70 may have better reflective performance, and the light emitting diode have better light extraction efficiency. However, the embodiments of the disclosure are not limited thereto, and the implementation is also applicable to the first insulation layer 50 described above and the third insulation layer 90 described below. The second insulation layer 70 has a patterned sixth through-hole structure 701, so that a metal electrode may be electrically connected to the metal layer 60 through the sixth through-hole structure 701. In order to make the second insulation layer 70 have better insulation protection and anti-leakage performance, in some preferred embodiments, a thickness of the second insulation layer 70 is selected to be between 50 and 2400 nm.

The light emitting diode further includes one or more first electrodes 81, which are located on the first conductive semiconductor layer 21 to be electrically connected to the first conductive semiconductor layer 21, and one or more second electrodes 82, which are located on the second conductive semiconductor layer 23 to be electrically connected to the second conductive semiconductor layer 23. For example, the first electrode 81 may be in contact with the first conductive semiconductor layer 21 through some of the sixth through-hole structures 701 located on the second insulation layer 70 to achieve electrical connection, and the second electrode 82 may be in contact with the metal layer 60 through other sixth through-hole structures 701 located on the second insulation layer 70 to be electrically connected to the second conductive semiconductor layer 23. The first electrode 81 and the second electrode 82 may be formed simultaneously using the same material in a unified process. For example, the first electrode 81 and the second electrode 82 may be metal electrodes made of nickel, gold, chromium, titanium, platinum, palladium, rhodium, iridium, aluminum, tin, indium, tantalum, copper, cobalt, iron, ruthenium, zirconium, tungsten, molybdenum, and a combination of one or more materials thereof, but the embodiments of the disclosure are not limited thereto. A width of the sixth through-hole structure 701 may be greater than or equal to 3 μm and less than or equal to 20 μm, and more preferably, greater than or equal to 6 μm and less than or equal to 12 μm.

The light emitting diode further includes a first pad electrode 83, a second pad electrode 84, and a third insulation layer 90. The third insulation layer 90 is located on the second insulation layer 70, and the first pad electrode 83 and the second pad electrode 84 are arranged on the third insulation layer 90. The third insulation layer 90 has a patterned seventh through-hole structure 901. The first pad electrode 83 may be in contact with the first electrode 81 through some of the seventh through-hole structures 901 located on the third insulation layer 90 to be electrically connected to the first conductive semiconductor layer 21, and the second pad electrode 84 may be in contact with the second electrode 82 through other seventh through-hole structures 901 located on the third insulation layer 90 to be electrically connected to the second conductive semiconductor layer 23. The third insulation layer 90 may be one of SiO₂, SiN, SiOₓN_{y}, TiO₂, Si₃N₄, Al₂O₃, TiN, AlN, ZrO₂, TiAlN, TiSiN, HfO₂, TaO₂ or MgF₂, or the distributed Bragg reflector (DBR) formed by repeatedly stacking two or more materials, but the embodiments of the disclosure are not limited thereto. The first pad electrode includes Ti, Al, Pt, Au, Ni, Sn, an alloy of any combination thereof, or a stack layer of any combination thereof. The second pad electrode includes Ti, Al, Pt, Au, Ni, Sn, an alloy of any combination thereof, or a stack layer of any combination thereof.

In order for the objectives, features, and advantages of the disclosure to be more comprehensible, specific embodiments accompanied with drawings are described in detail below.

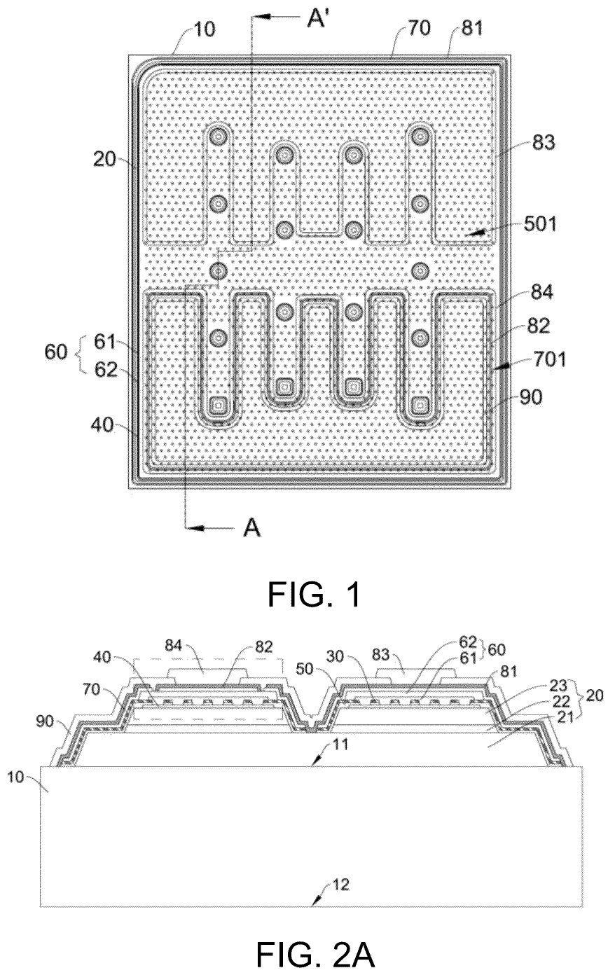

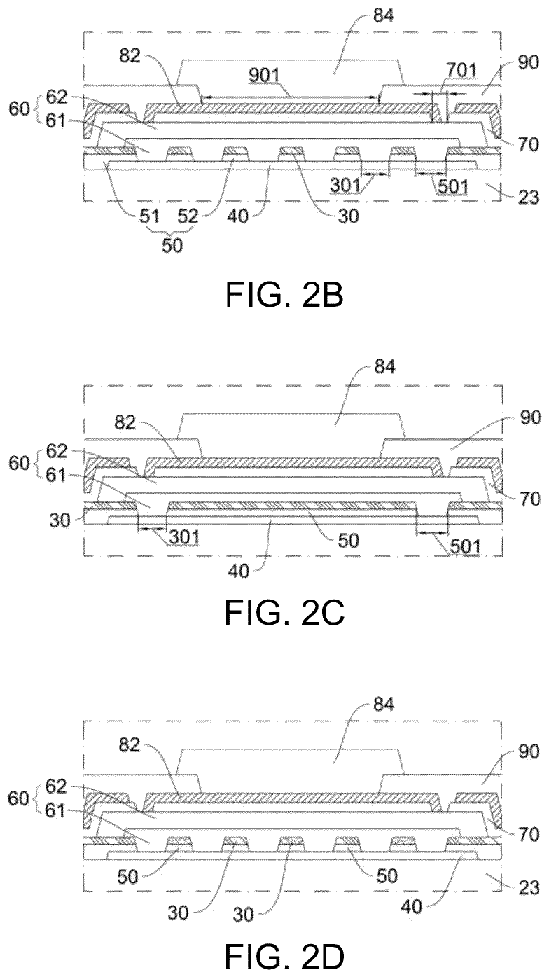

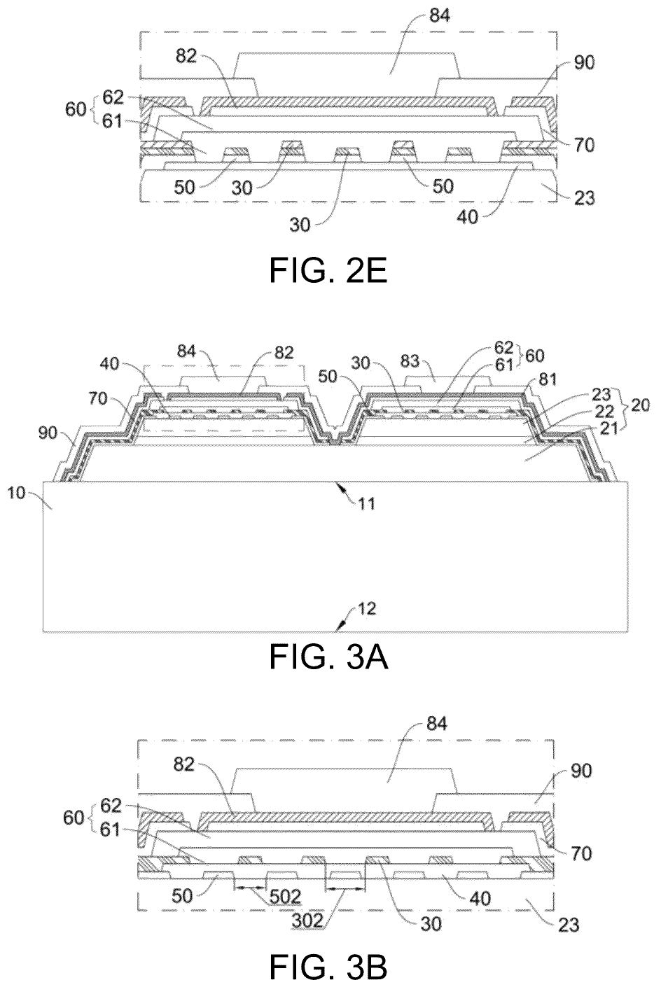

FIG. 1 is a schematic top view of a light emitting diode according to an embodiment of the disclosure. FIG. 2A is a schematic cross-sectional side view of a light emitting diode in FIG. 1. FIG. 2B is a schematic enlarged view of a structure in a dashed frame in FIG. 2A. It should be noted that the light emitting diode in FIG. 2A is shown along a section line A-A′.

Referring to FIGS. 1, 2A, and 2B together, the light emitting diode in the first embodiment includes at least one semiconductor epitaxial stack layer 20 disposed on the substrate 10. The semiconductor epitaxial stack layer 20 has the first conductive semiconductor layer 21, the light emitting layer 22, and the second conductive semiconductor layer 23 sequentially stacked and disposed from bottom to top. The semiconductor epitaxial stack layer 20 has one or more mesas. The mesas remove a portion of the second conductive semiconductor layer 23 and the light emitting layer 22 to expose a portion of a surface of the first conductive semiconductor layer 21. The mesas may be located inside the semiconductor epitaxial stack layer 20, located at an edge area of the semiconductor epitaxial stack layer 20, or located at both the inside and edge area of the semiconductor epitaxial stack layer 20. A portion of an upper surface of the first conductive semiconductor layer 21 exposed by the mesas may be used to achieve electrical connection with the first conductive semiconductor layer 21.

Continuing to refer to FIGS. 2A and 2B, the current expansion layer 40 for expanding the current is disposed on the second conductive semiconductor layer 23. The first insulation layer 50 covers the side wall of the semiconductor epitaxial stack layer 20, an edge of the portion of the upper surface, and a surface of the current expansion layer 40 close to the metal layer 60 (the upper surface and the side wall of the current expansion layer 40 are schematically covered in FIG. 2A). The first insulation layer 50 has the patterned second through-hole structure 501, and a portion of an upper surface of the current expansion layer 40 may be exposed through the second through-hole structure 501. The interface transition layer 30 (not shown in FIG. 1) covers the upper surface of the first insulation layer 50. In this embodiment, the interface transition layer 30 is made of the insulation metal oxide. The interface transition layer 30 has the patterned first through-hole structure 301, and the portion of the upper surface of the current expansion layer may be exposed through the first through-hole structure 301. The metal layer 60 includes the metal reflective layer 61 and the metal barrier layer 62. The metal reflective layer 61 is located above the semiconductor epitaxial stack layer 20, which covers a portion of the interface transition layer 30, and is at least partially in contact with the current expansion layer 40 through the first through-hole structure 301 and the second through-hole structure 501. The metal barrier layer 62 is located on the metal reflective layer 61, covers a side wall and a portion of the upper surface of the metal reflective layer 61, and may prevent the material of the metal reflective layer 61 from migrating. In the chip structure of the first embodiment, the insulation metal oxide is adopted as the interface transition layer 30 and is in direct contact with the metal reflective layer 61, which effectively improves the adhesion force of the metal layer 60. In addition, the first insulation layer 50 and the interface transition layer 30 (which is the insulation metal oxide) are adopted as the insulation layer, and may form an omnidirectional reflector with the metal layer 60 (the metal reflective layer 61). Specifically, on one hand, the adhesion force between the metal layer 60 (the metal reflective layer 61) and the first insulation layer 50 is increased, and on the other hand, the optical functional layer with gradient refractivity may be formed, thereby improving the light extraction efficiency. In addition, due to compactness of the insulation metal oxide, under a certain thickness, side coating thereof is better, which may effectively improve the reliability of the light emitting diode.

Continuing to refer to FIGS. 2A and 2B, the second insulation layer 70 is located on the first insulation layer 50. In this embodiment, it covers a portion of the upper surface of the interface transition layer 30 and a portion of the upper surface and the side wall of the metal layer 60. The second insulation layer 70 has the patterned sixth through-hole structure 701. The first electrode 81 and the second electrode 82 are respectively disposed on the second insulation layer 70. The first electrode 81 is electrically connected to the first conductive semiconductor layer 21 at the exposed mesa through some of the sixth through-hole structures 701, and the second electrode 82 is electrically connected to the metal barrier layer 62 through other sixth through-hole structures 701. The third insulation layer 90 is located on the second insulation layer 70, and the first pad electrode 83 and the second pad electrode 84 are arranged on the third insulation layer 90. The third insulation layer 90 has the patterned seventh through-hole structure 901. The first pad electrode 83 may be in contact with the first electrode 81 through some of the seventh through-hole structures 901 located on the second insulation layer 70 to be electrically connected to the first conductive semiconductor layer 21. The second pad electrode 84 may be in contact with the second electrode 82 through other seventh through-hole structures 901 located on the second insulation layer 70 to be electrically connected to the second conductive semiconductor layer 23.

FIG. 2C is a schematic enlarged view of the structure in the dashed frame in FIG. 2A according to the second embodiment of the disclosure.

Referring to both FIGS. 2A and 2C, in this embodiment, the first through-hole structure 301 and the second through-hole structure 501 on the interface transition layer 30 and the first insulation layer 50 are sparser than those in the first embodiment, thereby having the larger and more complete interface transition layer 30. Therefore, the metal layer 60 has more and more continuous contact surfaces with the interface transition layer 30, which may effectively improve the adhesion force of the metal layer 60, thereby improving the reliability of the light emitting diode.

In some embodiments, the contact surface between the interface transition layer 30 and the metal layer 60 may be formed by different insulation metal oxides to form a continuous or discontinuous alternative surface. FIG. 2D is a schematic enlarged view of the structure in the dashed frame in FIG. 2A according to a modified embodiment of the first embodiment of the disclosure. FIG. 2E is a schematic enlarged view of the structure in the dashed frame in FIG. 2A according to another modified embodiment of the first embodiment of the disclosure.

For example, referring to both FIGS. 2A and 2D, in this embodiment, the first insulation layer 50 is covered with the interface transition layer 30 alternately formed by multiple different materials at the same time (only two different materials are schematically shown in FIG. 2D), and the metal layer 60 covering thereon may effectively improve the adhesion force of the metal layer 60 by being in contact with the interface transition layer 30 formed by different materials at the same time, thereby improving the reliability of the light emitting diode.

Referring to both FIGS. 2A and 2E, in this embodiment, the first insulation layer 50 is covered with different numbers of layers of the interface transition layer 30 in different areas (FIG. 2D schematically shows only a single-layer and double-layer alternative structure), and the different numbers of layers of the interface transition layer 30 may be composed of the interface transition layers 30 formed by the same material, and may also be composed of the interface transition layers 30 formed by different materials. The metal layer 60 covering thereon may not only effectively improve the adhesion force of the metal layer 60 by being in contact the interface transition layer 30 formed by different insulation metal oxides at the same time, but also, due to the “rough-like” surface formed by a height difference in different areas, the adhesion force of the metal layer 60 on the entire interface transition layer 30 may be further improved, thereby improving the reliability of the light emitting diode.

FIG. 3A is a schematic cross-sectional side view of a light emitting diode according to the third embodiment of the disclosure. FIG. 3B is a schematic enlarged view of a structure in a dashed frame in FIG. 3A. It should be noted that the light emitting diode in FIG. 3A is shown along the section line A-A′.

Referring to FIGS. 1, 3A, and 3B together, the light emitting diode in the third embodiment includes the at least one semiconductor epitaxial stack layer 20 disposed on the substrate 10. The portion of the structure of is basically the same as that in the first embodiment. Thus, details in this regard will not be further reiterated in the following.

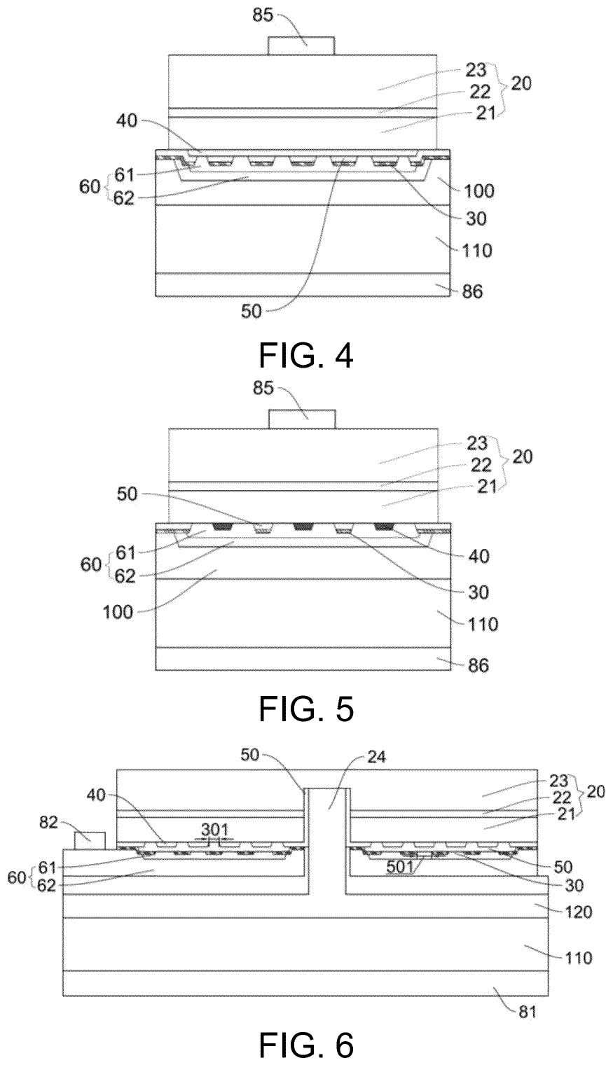

Continuing to referring to FIGS. 3A and 3B, the first insulation layer 50 covers the upper surface and the side wall of the semiconductor epitaxial stack layer 20. In this embodiment, the first insulation layer 50 has a patterned fourth through-hole structure 502. The current expansion layer 40 covers a surface of the first insulation layer 50 close to the metal layer (schematically covering the upper surface and the side wall of the first insulation layer 50 in FIG. 4), and is in contact with the second conductive semiconductor layer 23 through the fourth through-hole structure 502. The interface transition layer 30 covers the upper surface and the side wall of the current expansion layer 40, and the interface transition layer 30 has a patterned third through-hole structure 302. As a result, the metal layer 60 covering on the interface transition layer 30 is in contact with the current expansion layer 40 through the third through-hole structure 302. The metal layer 60 includes the metal reflective layer 61 and the metal barrier layer 62. The metal barrier layer 62 is located on the metal reflective layer 61, covering the side wall and a portion of the upper surface of the metal reflective layer 61. The configuration of the second insulation layer 70, connection electrodes (the first electrode 81 and the second electrode 82 are schematically shown in FIG. 4), the third insulation layer 90, and the pad electrode (the first pad electrode 83 and the second pad electrode 84 are schematically shown in FIG. 4) in the third embodiment may be specifically referred to that shown in FIGS. 2A and 2B, which is basically the same as that in the first embodiment. Thus, details in this regard will not be further reiterated in the following.

In the chip structure of the third embodiment, compared to the first embodiment, the first insulation layer 50 has more portions that are directly in contact with the semiconductor epitaxial stack layer 20, and a difference in the refractivity between the first insulation layer 50 and the semiconductor epitaxial stack layer 20 is greater than a difference in the refractivity between the current expansion layer 40 and the semiconductor epitaxial stack layer 20, so a light reflection effect is more excellent. In addition, referring to FIG. 4, the first insulation layer 50 and the interface transition layer 30 may also form a staggered complementation in structure, further improving the light extraction efficiency of the chip, and making the omnidirectional reflector formed by the first insulation layer 50 and the interface transition layer 30 (which is the insulation metal oxide) as the insulation layer, and the metal layer 60 more excellent in a refractive effect.

FIG. 4 is a schematic cross-sectional view of a light emitting diode according to the fourth embodiment of the disclosure. FIG. 5 is a schematic cross-sectional view of the light emitting diode according to a modified embodiment of the fourth embodiment shown in FIG. 4.

Referring to FIG. 4, the light emitting diode in the fourth embodiment may include, from top to bottom: a top electrode 85, the semiconductor epitaxial stack layer 20, the current expansion layer 40, the first insulation layer 50, the interface transition layer 30, the metal layer 60, a bond layer 100, a conductive substrate 110, and a back electrode 86. The semiconductor epitaxial stack layer 20 may include, from top to bottom, the first conductive semiconductor layer 21, the light emitting layer 22, and the second conductive semiconductor layer 23. The metal layer 60 may include, from top to bottom, the metal reflective layer 61 and the metal barrier layer 62. The bond layer 100 is used to bond the semiconductor epitaxial stack layer 20 to the conductive substrate 110, which may be Au—Au bonding, Au—In bonding, etc.

Referring to FIG. 5, in some embodiments, the current expansion layer 40 and the first insulation layer 50 may be disposed in an alternating array on the semiconductor epitaxial stack layer 20, or the current expansion layer 40 may not be disposed, and other structures are substantially the same as those in the fourth embodiment.

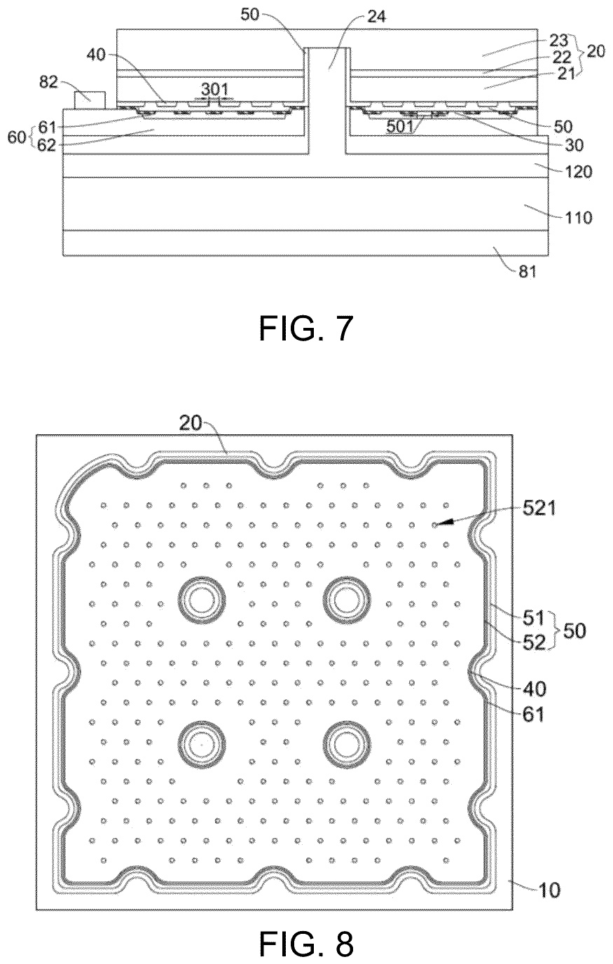

FIG. 6 is a schematic cross-sectional view of a light emitting diode according to the fifth embodiment of the disclosure. FIG. 7 is a schematic cross-sectional view of the light emitting diode according to a modified embodiment of the fifth embodiment shown in FIG. 6.

Referring to FIG. 6, the light emitting diode in the fifth embodiment may include, from top to bottom, the semiconductor epitaxial stack layer 20, the current expansion layer 40, the first insulation layer 50, the interface transition layer 30, the metal layer 60, the second insulation layer 70, a conductive connection layer 120, the conductive substrate 110, the first electrode 81, and the second electrode 82.

Specifically, the semiconductor epitaxial stack layer 20 may include, from top to bottom, the first conductive semiconductor layer 21, the light emitting layer 22, and the second conductive semiconductor layer 23, and has at least one concave portion 24 (only one concave portion 24 is schematically shown in FIG. 6). The concave portion 24 extends from a lower surface of the semiconductor epitaxial stack layer 20 sequentially through the second conductive semiconductor layer 23 and the light emitting layer 22 to the first conductive semiconductor layer 21. The first insulation layer 50 is formed on the surface of the current expansion layer 40 and extends to cover a side wall of the concave portion 24. The first insulation layer 50 has the patterned second through-hole structure 501 to expose a portion of the surface of the current expansion layer 40. The interface transition layer 30 covers the surface of the first insulation layer 50, and the interface transition layer 30 has the patterned first through-hole structure 301. The metal layer 60 includes the metal reflective layer 61 and the metal barrier layer 62. The metal reflective layer 61 is located on the interface transition layer 30 and covers a portion of the interface transition layer 30 to improve the adhesion force of the metal layer 60, and the metal reflective layer 61 is in contact with the exposed current expansion layer 40 through the first through-hole structure 301 and the second through-hole structure 501. The metal barrier layer 62 is located on the metal reflective layer 61, covers the side wall and the portion of the upper surface of the metal reflective layer 61, and exposes the portion of the surface at the same time to dispose the second electrode 82.

The second insulation layer 70 is disposed on a surface of the metal barrier layer 62 away from one side of the semiconductor epitaxial stack layer 20 and covers the side wall of the concave portion 24. In this embodiment, the interface transition layer 30 is an insulation metal oxide. Therefore, the side wall of the concave portion 24 is sequentially covered with the first insulation layer 50, the interface transition layer 30, and the second insulation layer 70 from the inside to the outside. The conductive connection layer 120 is located on a surface of the second insulation layer 70 and is filled with the concave portion 24 to be electrically connected to the first conductive semiconductor layer 21, and further includes a bonding material for bonding to the conductive substrate 110 at the same time. The conductive substrate 110 is disposed on a surface of the conductive connection layer 120 away from one side of the semiconductor epitaxial stack layer 20. The first electrode 81 is disposed on a side surface of the conductive substrate 110 away from the semiconductor epitaxial stack layer 20, thereby forming an electrical connection with the first conductive semiconductor layer 21 sequentially through the conductive substrate 110 and the conductive connection layer 120. The second electrode 82 is disposed on the surface of the exposed metal barrier layer 62, thereby forming an electrical connection with the second conductive semiconductor layer 23 sequentially through the metal barrier layer 62, the metal reflective layer 61, and the current expansion layer 40. The metal barrier layer 62 and the conductive connection layer 120 are electrically isolated by the second insulation layer 70.

A difference between the modified embodiment shown in FIG. 7 and the fifth embodiment is that for the configuration of the interface transition layer 30, the current expansion layer 40, and the first insulation layer 50, reference may be made to the structure in the third embodiment. Thus, details in this regard will not be further reiterated in the following.

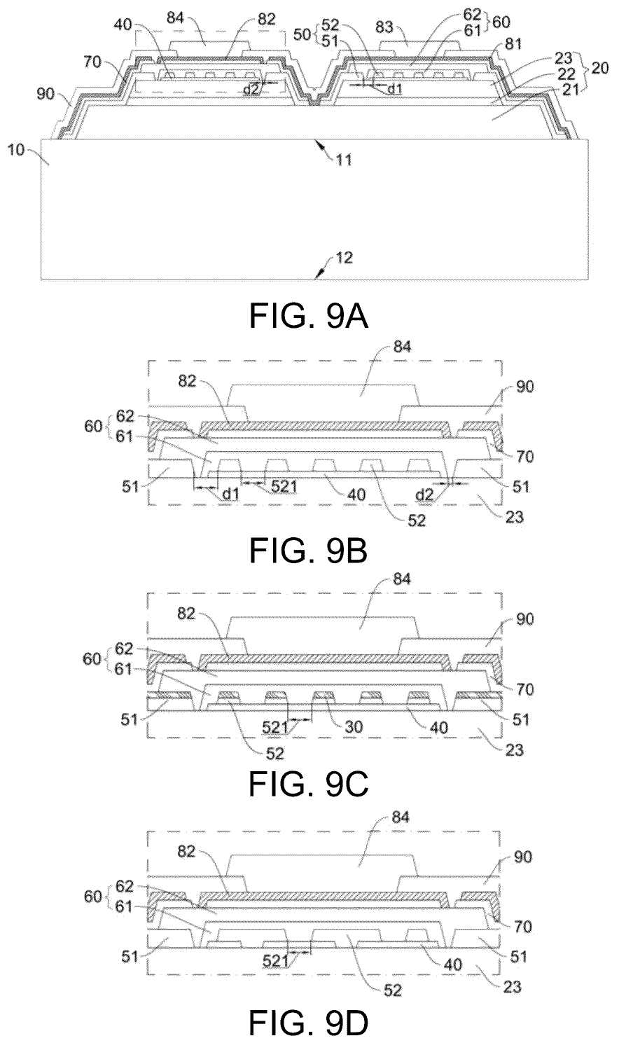

FIG. 8 is a schematic top view of a portion of a structure of a light emitting diode according to the sixth embodiment of the disclosure. FIG. 9A is a schematic side view of the light emitting diode provided in the sixth embodiment. FIG. 9B is a schematic enlarged view of a structure in a dashed frame in FIG. 9A.

Referring to FIGS. 8, 9A, and 9B together, the light emitting diode in the sixth embodiment includes the at least one semiconductor epitaxial stack layer 20 disposed on the substrate 10, which is basically the same as that in the first embodiment. Thus, details in this regard will not be further reiterated in the following.

Referring to FIGS. 9A and 9B, the current expansion layer 40 for expanding the current is disposed on the second conductive semiconductor layer 23. The first insulation layer 50 includes a first portion 51 covering the side wall and an edge of the portion of the upper surface of the semiconductor epitaxial stack layer 20, and a second portion 52 covering a portion of the upper surface of the current expansion layer 40 close to one side of the metal layer 60. A first gap d1 is provided between the first portion 51 and the second portion 52. The metal layer 60 includes the metal reflective layer 61, and projections of edges of the metal reflective layer 61 and the current expansion layer 40 in a direction perpendicular to the semiconductor epitaxial stack layer 20 fall within the first gap d1. In this embodiment, the projection of the current expansion layer 40 in the direction perpendicular to the semiconductor epitaxial stack layer 20 falls within a range of the metal reflective layer 61, so that as shown in FIG. 9B, an outer portion of the edge of the metal reflective layer 61 is in contact with the semiconductor epitaxial stack layer 20, while an inner portion of the edge is in contact with the current expansion layer 40. On one hand, an issue of poor adhesion force and easy falling off of the edge of the metal reflective layer 61 when covering the first insulation layer 50 is improved. At the same time, compared to using the second portion 52 to cover the current expansion layer 40 such that the metal reflective layer 61 is directly in contact with the exposed second conductive semiconductor layer 23, the current expansion layer 40 has a larger area, so that the chip has better current scalability and may effectively reduce damage to the light emitting diode caused by electrostatic discharge (ESD). On the other hand, the chip structure forms the first portion 51 divided by the first gap d1 and is located outside the first gap d1 to protect an upper surface periphery and an outer ring area of the side wall of the semiconductor epitaxial stack layer 20, while the second portion 52 is located as an inner ring area of a middle portion of the upper surface of the semiconductor epitaxial stack layer 20, thereby forming a moat effect, effectively protecting a boundary of MESA, and thus improving the reliability of the light emitting diode. In some embodiments, a spacing of the first gap d1 may be greater than 4 μm and less than 20 m. Selecting a range of the spacing may, on the one hand, effectively reduce damage to the light emitting diode caused by the electrostatic discharge (ESD), and on the other hand, better improve photoelectric performance of the light emitting diode.

Continuing to refer to FIGS. 9A and 9B, the second portion 52 has a patterned fifth through-hole structure 521, and a portion of the upper surface of the current expansion layer 40 may be exposed through the fifth through-hole structure 521. The metal reflective layer 61 is located above the semiconductor epitaxial stack layer 20, covers a portion of the interface transition layer 30, and is at least partially in contact with the current expansion layer 40 through the fifth through-hole structure 521. A second gap d2 is provided between the edge of the metal reflective layer 61 projected in the direction perpendicular to the semiconductor epitaxial stack layer 20 and the edge of the first portion 51 close to one side of the metal reflective layer 61 projected in the direction perpendicular to the semiconductor epitaxial stack layer 20. A spacing of the second gap d2 may be greater than 0.5 μm and less than 5 μm, greater than 1 μm and less than 5 μm, greater than 2 μm and less than 5 μm, or greater than 3 μm and less than 5 m. When the edge of the metal reflective layer 61 is located at the first portion 51 of the first insulation layer 50, the metal reflective layer 61 is at risk of falling off. By controlling the two gaps, the metal reflective layer 61 may be effectively prevented from covering the surface of the first portion 51 of the first insulation layer 50. In the sixth embodiment, for the configuration of the metal barrier layer 62, the second insulation layer 70, the connection electrodes (the first electrode 81 and the second electrode 82 are schematically shown in FIG. 9A), the third insulation layer 90, and the pad electrode (the first pad electrode 83 and the second pad electrode 84 are schematically shown in FIG. 9A), reference may be specifically made to that as shown in FIGS. 9A and 9B, which is basically the same as that in the first embodiment. Of course, the metal barrier layer 62 therein may be disposed in the same manner as shown in the drawing, or the edge thereof may not cover the surface of the first insulation layer 50, but may have a similar configuration to the metal reflective layer 61. That is, the edge thereof covers the current expansion layer 40 and/or the semiconductor epitaxial stack layer 20. Thus, details in this regard will not be further reiterated in the following.

FIG. 9C shows the first modified embodiment of the structure in the dashed frame in FIG. 9A according to the sixth embodiment of the disclosure.

Referring to both FIGS. 9A and 9C, in this embodiment, the first insulation layer 50 may be covered with the interface transition layer 30 to enhance the adhesion of the metal reflective layer 61.

FIG. 9D shows the second modified embodiment of the structure in the dashed frame in FIG. 9A according to the sixth embodiment of the disclosure.

Referring to both FIGS. 9A and 9D, in this embodiment, the current expansion layer 40 may have a through hole exposing the surface of the second conductive semiconductor layer 23. The series of through holes is preferably staggered with the fifth through-hole structure 521 on the second portion 52 of the first insulation layer 50. In this way, light absorption of the current expansion layer 40 may be reduced, thereby improving the light extraction efficiency of the light emitting diode.

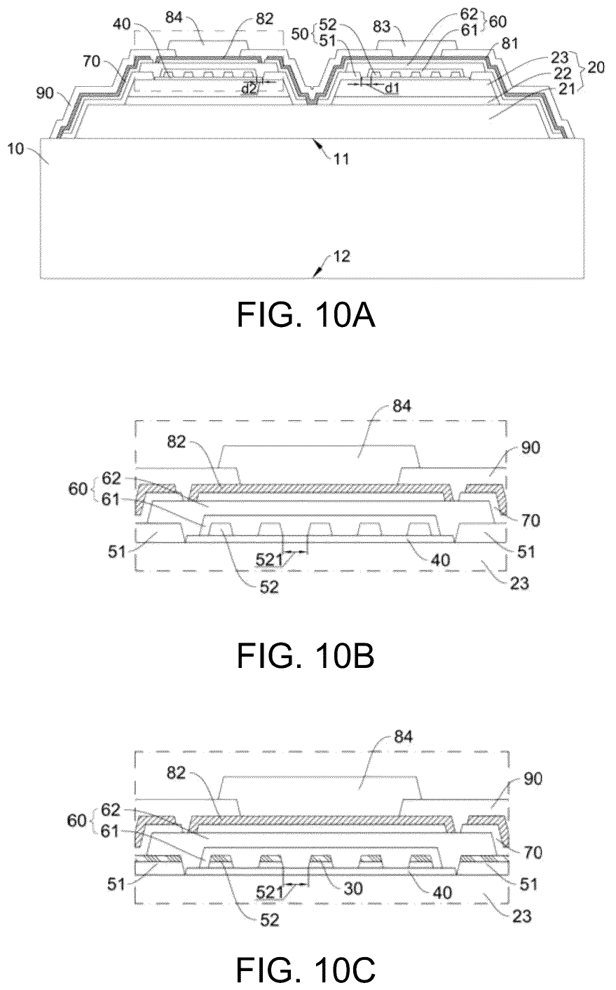

FIG. 10A is a schematic side view of a structure of a light emitting diode according to the seventh embodiment of the disclosure. FIG. 10B is a schematic enlarged view of the structure in a dashed frame in FIG. 10A.

Referring to both FIGS. 10A and 10B, a difference between the seventh embodiment and the sixth embodiment is that the projection of the metal reflective layer 61 in the direction perpendicular to the semiconductor epitaxial stack layer 20 falls within a range of the current expansion layer 40, so that a portion of the metal reflective layer 61 at the edge thereof may be in contact with the current expansion layer 40 as shown in FIG. 10B, thereby improving the issue of poor adhesion and easy falling off when the edge of the metal reflective layer 61 is covered on the first insulation layer 50. Compared to the sixth embodiment, since it has a larger area of the current expansion layer 40, it has a better effect in effectively reducing the electrostatic discharge (ESD), and an issue of light absorption of the current expansion layer 40 leads to relatively lower light extraction efficiency.

FIG. 10C shows the first modified embodiment of the structure in the dashed frame in FIG. 10A according to the seventh embodiment of the disclosure.

Referring to both FIGS. 10A and 10C, in this embodiment, the first insulation layer 50 may be covered with the interface transition layer 30 to enhance the adhesion of the metal reflective layer 61.

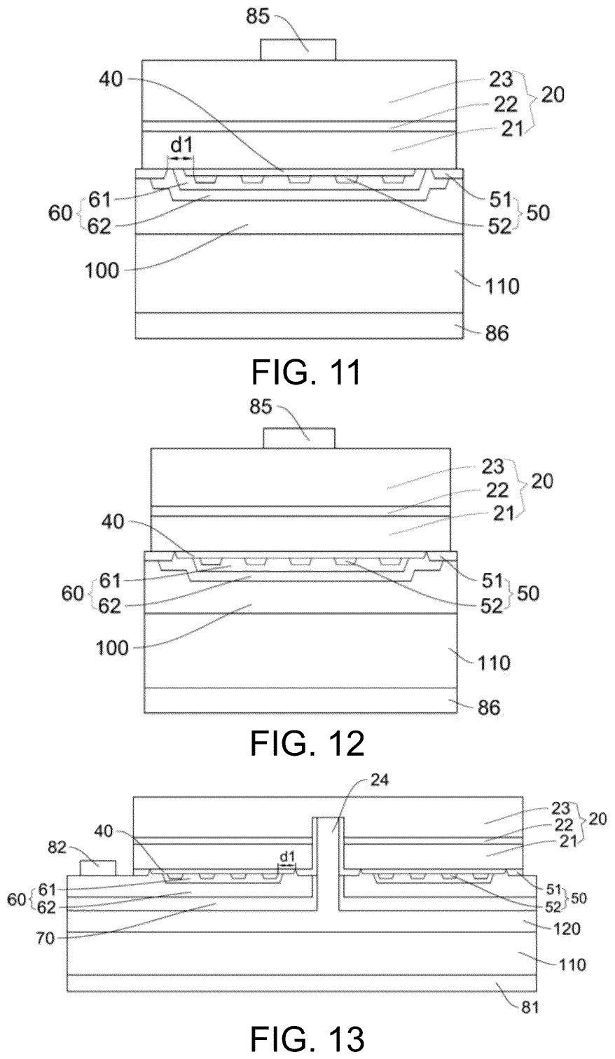

FIG. 11 is a schematic cross-sectional view of a light emitting diode according to the eighth embodiment of the disclosure.

Referring to FIG. 11, the light emitting diode in the eighth embodiment may include, from top to bottom, the top electrode 85, the semiconductor epitaxial stack layer 20, the current expansion layer 40, the first insulation layer 50, the metal layer 60, the bond layer 100, the conductive substrate 110, and the back electrode 86, which is basically the same as the structure in the fourth embodiment. A difference is that the metal layer 60 is the metal reflective layer 61, which is covered with the metal barrier layer 62. The first insulation layer 50 thereof includes the first portion 51 covering the edge of the portion of the upper surface of the semiconductor epitaxial stack layer 20, and the second portion 52 covering the portion of the upper surface of the current expansion layer 40 close to one side the metal layer 60. The first gap d1 is provided between the first portion 51 and the second portion 52, and the projections of the edges of the metal layer 60 and the current expansion layer 40 in the direction perpendicular to the semiconductor epitaxial stack layer 20 fall within the first gap d1. In this embodiment, the projection of the current expansion layer 40 in the direction perpendicular to the semiconductor epitaxial stack layer 20 falls within the range of the metal reflective layer 61. In the chip structure of this embodiment, compared to the direct contact with the current expansion layer 40, an edge portion of the metal reflective layer 61 is in direct contact with the semiconductor epitaxial stack layer 20, so that the adhesion of the metal reflective layer 61 is better.

FIG. 12 is a schematic cross-sectional view of a light emitting diode according to the ninth embodiment of the disclosure.

Referring to both FIGS. 11 and 12, a difference between the ninth embodiment and the eighth embodiment is that the projection of the metal reflective layer 61 in the direction perpendicular to the semiconductor epitaxial stack layer 20 falls within the range of the current expansion layer 40. In the chip structure of this embodiment, compared to the direct contact with the first insulation layer 50, the edge portion of the metal reflective layer 61 is in direct contact with the current expansion layer 40, so that the adhesion of the metal reflective layer 61 is better. In addition, under the structure, a coverage area of the current expansion layer 40 is larger, so that a current expansion effect is also better.

FIG. 13 is a schematic cross-sectional view of a light emitting diode according to the tenth embodiment of the disclosure.

Referring to FIG. 13, the light emitting diode in the tenth embodiment includes, from top to bottom, the semiconductor epitaxial stack layer 20, the current expansion layer 40, the first insulation layer 50, the metal reflective layer 61, the second insulation layer 70, the conductive connection layer 120, the conductive substrate 110, the first electrode 81, and the second electrode 82, which is basically the same as the structure in the fifth embodiment. A difference is that the first insulation layer 50 includes the first portion 51 covering the edges of the side wall and the portion of the upper surface of the semiconductor epitaxial stack layer 20, and the second portion 52 covering the portion of the upper surface of the current expansion layer 40 close to one side of the metal layer 60. The first gap d1 is provided between the first portion 51 and the second portion 52, and the projections of the edges of the metal reflective layer 61 and the current expansion layer 40 in a direction perpendicular to the semiconductor epitaxial stack layer 20 fall within the first gap d1. In this embodiment, the projection of the current expansion layer 40 in the direction perpendicular to the semiconductor epitaxial stack layer 20 falls within the range of the metal reflective layer 61, and optionally, the interface transition layer is disposed, and the configuration of the rest of the structure may be adaptively disposed with reference to FIG. 13 and the structure of the light emitting diode in the fifth embodiment. Thus, details in this regard will not be further reiterated in the following.

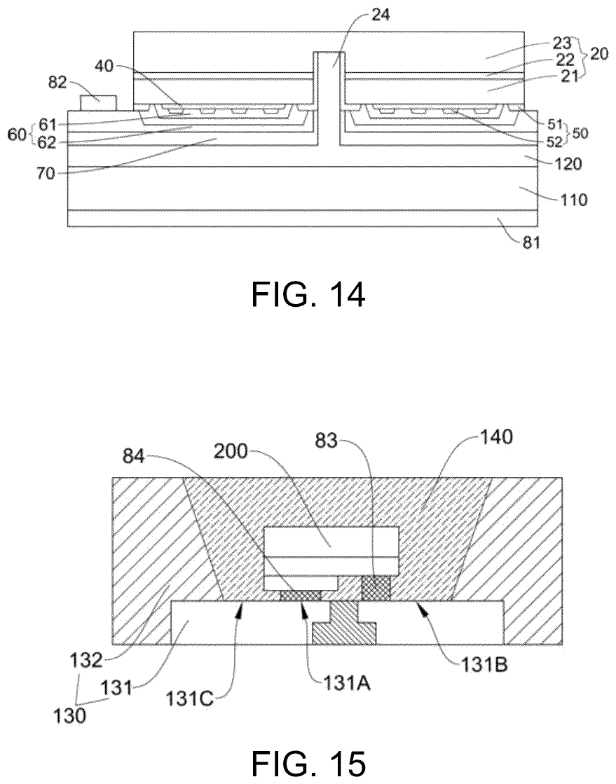

FIG. 14 is a schematic cross-sectional view of a light emitting diode according to the eleventh embodiment of the disclosure.

Referring to both FIGS. 13 and 14, a difference between the eleventh embodiment and the tenth embodiment is that the projection of the metal reflective layer 61 in the direction perpendicular to the semiconductor epitaxial stack layer 20 falls within the range of the current expansion layer 40.

It should be noted that in the several implementations listed in the above embodiments and modified embodiments, it is obvious that the various features shown may be combined with each other to form a new technical solution. Thus, details in this regard will not be further reiterated in the following.

Based on the above, compared to the related art, the light emitting diode provided in the disclosure has higher reliability and structural stability.

The light emitting diode in the disclosure may be applied to a light emitting device or a display device. The light emitting device may be used in, but not limited to, COB (chip on board) illumination, UV, bulb lamps, flexible filament lamps, etc. The display device may be a backlight display or an RGB direct display device.

The light emitting diode in the disclosure may be a flip-chip light emitting diode. The pad electrode may be connected to other application-type circuit substrates using solder paste material through reflow soldering and high-temperature treatment processes to be made into the display device, such as the backlight display or an RGB display screen.

According to one aspect of the disclosure, a light emitting device is provided, such as vehicle illumination, plant illumination, etc. The light emitting device includes a holder and the flip-chip light-emitting diode in this application fixed on the holder. The holder includes, but is not limited to, only a COB holder or a COG holder, and may also be an SMD holder, etc.

As an embodiment, referring to FIG. 15, the light emitting device includes a holder 130, a package layer 140, and a flip-chip light emitting diode 200. In this embodiment, the flip-chip light emitting diode 200 may be the light emitting diode in the aforementioned embodiment.

Preferably, the holder 130 may be a flat type, or a reflective cup is disposed around an area on the holder 130 for installing the flip-chip light emitting diode 200. The reflective cup defines a space for accommodating the flip-chip light emitting diode 200.

Referring to FIG. 15, the holder 130 includes a bottom 131 and a side wall 132. The side wall 132 is located around the area where the flip-chip light emitting diode 200 is installed to form a reflective cup structure. An installation area 131A, a first solder wire area 131B, and a second solder wire area 131C are disposed on an upper surface of the bottom 131. The first solder wire area 131B and the second solder wire area 131C are electrically isolated from each other. The flip-chip light emitting diode 200 is installed on the installation area 131A and is connected to the first solder wire area 131B and the second solder wire area 131C through the first pad electrode 83 and the second pad electrode 84 respectively. The package layer 140 seals the flip-chip light emitting diode 200 on the holder 130.

For example, surfaces of the first pad electrode 83 and the second pad electrode 84 of the flip-chip light emitting diode 200 may be plated with a solderable metal layer, such as a conductive solder paste, and upper surfaces of the first solder wire area 131B and the second solder wire area 131C may also be provided with a metal electrode, so that a flip chip may be soldered to the corresponding solder wire area through eutectic soldering or solder paste.

Preferably, the flip-chip light emitting diode 200 is applied to the backlight display or the RGB display screen, and hundreds, thousands, or tens of thousands of small-sized flip-chip light emitting diodes 200 are integrated and installed on an application substrate or a package substrate, so as to form a light source portion of the backlight display device or the RGB display device.

Although terms such as the substrate, semiconductor epitaxial stack layer, first conductive semiconductor layer, light emitting layer, second conductive semiconductor layer, current expansion layer, metal layer, bond layer, conductive substrate are frequently used herein, it does not exclude the possibility of using other terms. These terms are used only to more conveniently describe and explain the essence of the disclosure. It would be contrary to the spirit of the disclosure to interpret them as any additional limitations. The terms “first”, “second”, etc. (if any) in the specification and claims of the embodiments of the disclosure and the above drawings are used to distinguish similar objects and are not necessarily used to describe a specific order or sequence.

What is claimed is:

1. A light emitting diode, comprising:
a semiconductor epitaxial stack layer comprising a first conductive semiconductor layer, a light emitting layer, and a second conductive semiconductor layer sequentially stacked and disposed;
an interface transition layer located on the semiconductor epitaxial stack layer, the interface transition layer comprising an insulation metal oxide or a stack layer of the insulation metal oxides;
a first insulation layer disposed between the interface transition layer and the semiconductor epitaxial stack layer;
a metal layer covering a portion of a surface of the interface transition layer and electrically connected to the semiconductor epitaxial stack layer.

2. The light emitting diode according to claim 1, wherein a thickness of the interface transition layer is greater than 3 nm and less than 400 nm.

3. The light emitting diode according to claim 1, wherein a thickness of the interface transition layer is greater than 10 nm and less than 200 nm.

4. The light emitting diode according to claim 1, wherein refractivity of the interface transition layer is greater than 1.5 and less than to 3.5.

5. The light emitting diode according to claim 1, wherein the insulation metal oxide comprises at least one of TiO₂, ZrO₂, HfO₂, Ta₂O₅, Al₂O₃, Nb₂O₅, Y₂O₃, MgO, La₂O₃, SrTiO₃, BaTiO₃, and CeO₂.

6. The light emitting diode according to claim 1, wherein a contact surface between the interface transition layer and the metal layer is formed by different insulation metal oxides to form a continuous or discontinuous alternative surface.

7. The light emitting diode according to claim 1, wherein a thickness of the first insulation layer is greater than 50 nm and less than 2400 nm.

8. The light emitting diode according to claim 1, wherein the first insulation layer comprises at least one of SiO₂, SiN, SiOₓN_{y}, TiO₂, Si₃N₄, Al₂O₃, TiN, AlN, ZrO₂, TiAlN, TiSiN, HfO₂, TaO₂ and MgF₂, or a combination thereof.

9. The light emitting diode according to claim 1, wherein a current expansion layer is further disposed between the interface transition layer and the semiconductor epitaxial stack layer, and a portion of the metal layer is electrically connected to the semiconductor epitaxial stack layer through the current expansion layer.

10. The light emitting diode according to claim 9, wherein the first insulation layer at least covers a portion of a surface of the current expansion layer close to one side of the metal layer, the interface transition layer has a patterned first through-hole structure, and the first insulation layer has a patterned second through-hole structure;
at least a portion of the metal layer is in contact with the current expansion layer through the first through-hole structure and the second through-hole structure sequentially, and at least a portion of the current portion layer is in contact with the semiconductor epitaxial stack layer.

11. The light emitting diode according to claim 10, wherein a diameter of the first through-hole structure is greater than 3 μm and less than 20 μm, a diameter of the second through-hole structure is greater than 3 μm and less than 20 μm, and a distance between the adjacent first through-hole structures is greater than 10 μm and less than 50 μm, and a distance between adjacent second through-hole structures is greater than 10 μm and less than 50 m.

12. The light emitting diode according to claim 9, wherein the interface transition layer has a patterned third through-hole structure, and the metal layer is in contact with the current expansion layer through the third through-hole structure;
the first insulation layer has a patterned fourth through-hole structure, the current expansion layer at least covers a portion of a surface of the first insulation layer close to one side of the metal layer, and the current expansion layer is in contact with the semiconductor epitaxial stack layer through the fourth through-hole structure.

13. The light emitting diode according to claim 9, wherein the first insulation layer comprises a first portion at least covering a side wall of the semiconductor epitaxial stack layer, and a second portion at least covering a portion of a surface of the current expansion layer, and a first gap is provided between the first portion and the second portion;
a projection of an edge of the metal layer in a direction perpendicular to the semiconductor epitaxial stack layer falls within the first gap.

14. The light emitting diode according to claim 13, wherein a projection of an edge of the current expansion layer in the direction perpendicular to the semiconductor epitaxial stack layer falls within the first gap.

15. The light emitting diode according to claim 13, wherein a spacing of the first gap is greater than 4 μm and less than 20 μm.

16. The light emitting diode according to claim 13, wherein the second portion has a patterned fifth through-hole structure, and a portion of the metal layer is in contact with the current expansion layer through the fifth through-hole structure.

17. The light emitting diode according to claim 13, wherein a second gap is provided between the edge of the metal layer projected in the direction perpendicular to the semiconductor epitaxial stack layer and an edge of the first portion close to one side of the metal layer projected in the direction perpendicular to the semiconductor epitaxial stack layer.

18. The light emitting diode according to claim 17, wherein a spacing of the second gap is greater than 0.5 μm and less than 5 μm.

19. The light emitting diode according to claim 13, wherein a projection of the metal layer in the direction perpendicular to the semiconductor epitaxial stack layer falls within a range of the current expansion layer.

20. The light emitting diode according to claim 13, wherein a projection of the current expansion layer in the direction perpendicular to the semiconductor epitaxial stack layer falls within a range of the metal layer.
